(19) United States
(12) Patent Application Publication
(10) Pub. No.: US 2008/0105884 A1
(43) Pub. Date: May 8, 2008

(54) Light-emitting diode

(75) Inventors: Ching-Huei Wu, San Chung City (TW); Yuan-Cheng Chin, San Chung City (TW); Tung-Ching Wu, San Chung City (TW)

Correspondence Address: TROXELL LAW OFFICE PLLC;SUITE 1404, 5205 LEESBURG PIKE, FALLS CHURCH, VA, 22041, US

(73) Assignee: Unity Opto Technology Co., Ltd.

(21) Appl. No.: 11/592,236

(22) Filed: Nov. 3, 2006

(51) Int. Cl. H01L 33/00

(52) U.S. Cl. 257/88; 257/E33.001

(57) ABSTRACT

A light-emitting diode comprises: a coupling base; several light-emitting chips; and an adhesive for sealing the coupling base, wherein the coupling base has a coupling part and at least two frame pairs mounted therein. The light-emitting chips are fixed on the coupling part. The light-emitting chips are electrically connected with these two frame pairs, which are controlled by two control terminals simultaneously.

### FIELD OF THE INVENTION

The present invention relates to a multi-chip light-emitting diode or the like, and more particularly to a light-emitting diode capable of controlling several light-emitting chips separately.

### BACKGROUND OF THE INVENTION

The light-emitting diode is a high-effect light-emitting device and it is also a tiny solid-state illuminator. The light-emitting device is principally composed of a semiconductor PN junction structure. When the voltage is applied bilaterally to the PN junction, the electrons and the holes are formed and shifted toward the PN junction so as to allow the electrons and the holes to combine with one another for generating the photons.

Referring to FIG. 5, a cross-sectional view of a conventional light-emitting diode is shown. The light-emitting diode A has two cathode and anode pins A1 and A2. The pin A2 has a trench A21 on the upper end for holding a light-emitting chip A3. The lower surface of the light-emitting chip A3 is directly, electrically connected to the pin A2 to obtain the cathode potential. Besides, the light-emitting chip A3 is further connected to the pin A1 via a bonding wire A4 so as to obtain the anode potential. Besides, a transparent resin layer A5 is applied to cover the light-emitting chip A3 and the pins A1, A2 so as to fix and protect the light-emitting chip A3 and the bonding wire A4.

However, in order to emit different-colored lights, several light-emitting chips can be mounted on a single light-emitting diode. As a result, the mixed lighting can be produced after the light-emitting diode is electrified. However, in this light-emitting diode, these light-emitting chips are coupled with the same cathode pin. In addition, the anode pins that have an amount equal to that of the light-emitting chips are provided. Accordingly, these light-emitting chips are simultaneously lighted up when the light-emitting diode is electrified. Therefore, these light-emitting chips cannot be controlled separately.

In view of the foregoing description, the motive of the present invention is to provide the general public with a light-emitting diode capable of controlling several light-emitting chips separately.

### SUMMARY OF THE INVENTION

It is a principal object of the present invention to provide a light-emitting diode capable of controlling several light-emitting chips separately.

It is another object of the present invention to provide a light-emitting diode having a large-area coupling part for coupling with several light-emitting chips.

In order to achieve the above-mentioned objects, a light-emitting diode is comprised of a coupling base; several light-emitting chips; and an adhesive for sealing the coupling base, wherein the coupling base has a coupling part and at least two frame pairs disposed therein. The light-emitting chips are fixed on the coupling part and electrically connected with these two frame pairs, which are controlled by two control terminals simultaneously.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational view showing a preferred embodiment of the present invention.

FIG. 2 is a top view showing the preferred embodiment of the present invention.

FIG. 3 is a schematic, cross-sectional view showing the preferred embodiment of the present invention.

FIG. 4 is a schematic view showing the arranged frames of the present invention.

FIG. 5 is a cross-sectional view showing a conventional light-emitting diode.

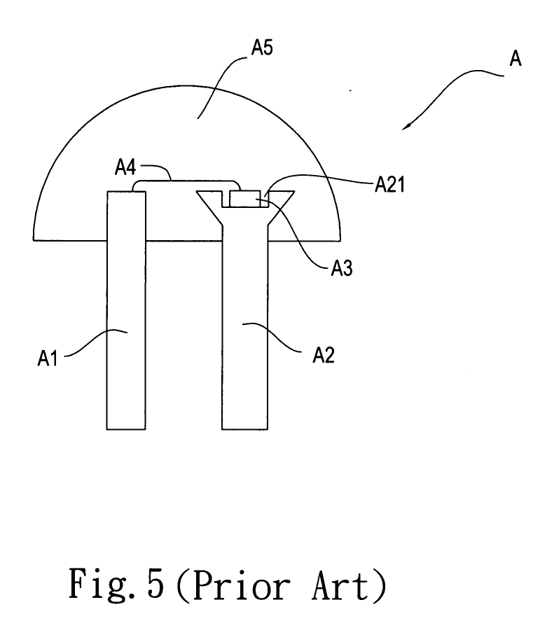

### DETAILED DESCRIPTION OF THE PREFERRED EMBODIMENT

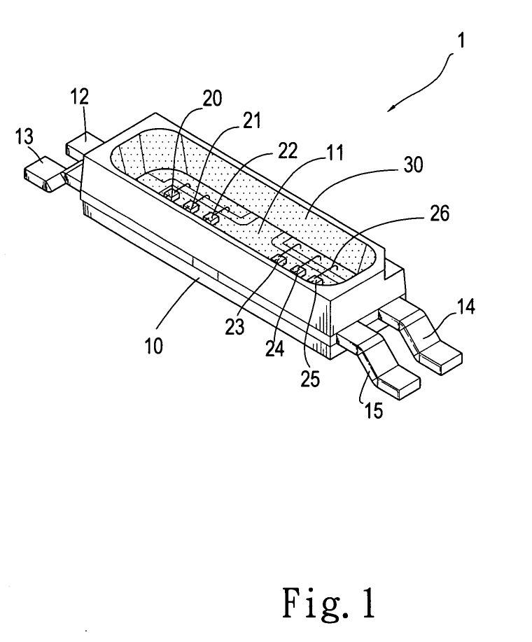

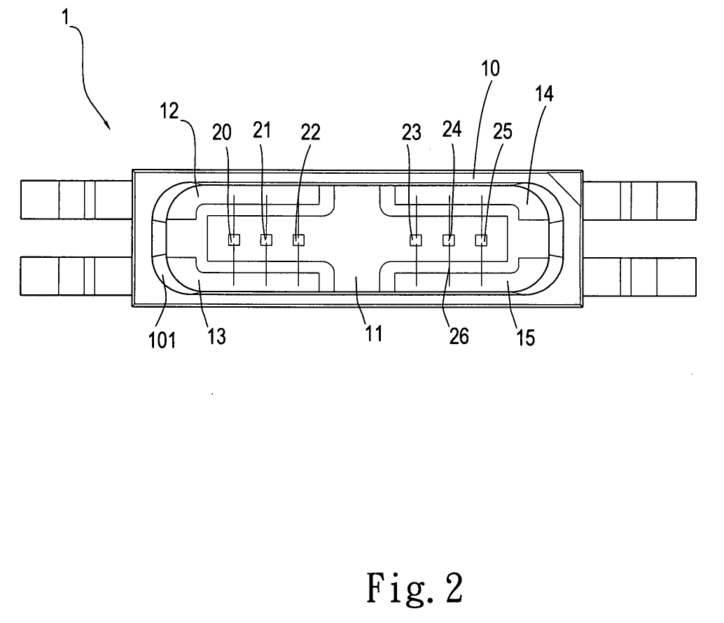

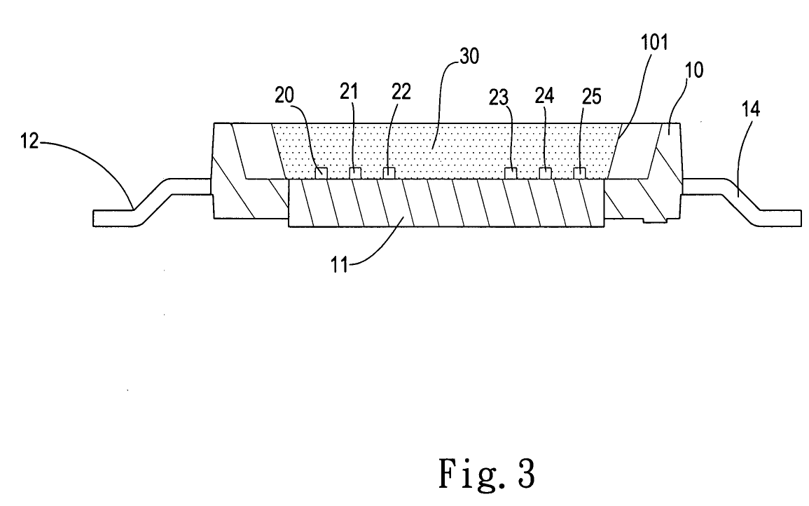

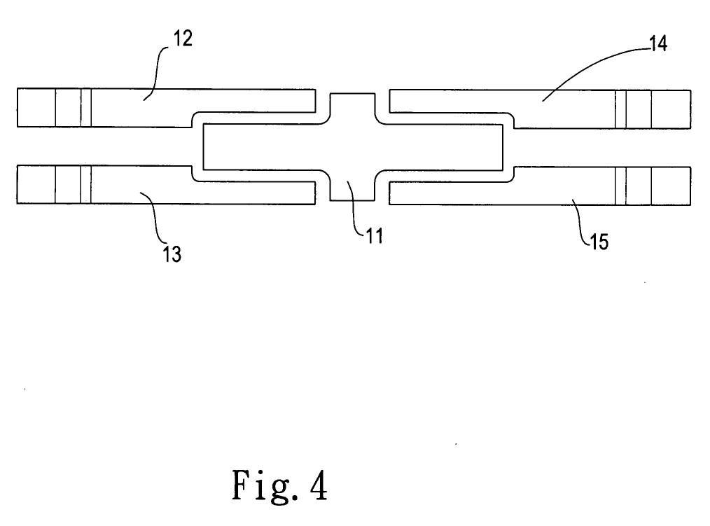

Referring to FIGS. 1 through 3, a light-emitting diode 1 of the present invention comprises a coupling base 10, several light-emitting chips, several bonding wires 26, and an adhesive 30. The coupling base 10 has a coupling part 11 and at least two frame pairs disposed therein. In this preferred embodiment, there are two frame pairs including four frames 12, 13, 14, and 15. The coupling part 11 is a cross-shaped plate. These four frames 12-15 of these two frame pairs are arranged around the coupling part 11. As shown in FIG. 4, when the coupling part 11 and the frames 12-15 are assembled together so as to form the coupling base 10 that has a trench 101 formed thereon, the frames 12-15 are spaced by a certain distance from the coupling part 11. Accordingly, the frames 12-15 do not touch the coupling part 11. The light-emitting chips are disposed on the coupling part 11. In this preferred embodiment, there are six light-emitting chips including a first light-emitting chip 20, a second light-emitting chip 21, a third light-emitting chip 22, a fourth light-emitting chip 23, a fifth light-emitting chip 24, and a sixth light-emitting chip 25, wherein the first light-emitting chip 20, the second light-emitting chip 21, and the third light-emitting chip 22 are electrically connected to the frames 12 and 13. In addition, the fourth light-emitting chip 23, the fifth light-emitting chip 24, and the sixth light-emitting chip 25 are also electrically connected to the frames 14 and 15. Besides, the adhesive 30 is filled into the trench 101 of the coupling base 10 so as to package these six light-emitting chips 20-25 and the bonding wires 26 in the trench 101. The assembly of the present invention is thus completed.

The light-emitting diode 1 of the present invention has two groups of independent cathode and anode pins including the frames 12-15. In other words, the light-emitting chips 20-25 are divided into two groups, and the frames 12-15 are controlled by two control terminals simultaneously. Accordingly, the first light-emitting chip 20, the second light-emitting chip 21, and the third light-emitting chip 22 are controlled by the control terminal that connects with the frames 12 and 13. In addition, the fourth light-emitting chip 23, the fifth light-emitting chip 24, and the sixth light-emitting chip 25 are controlled by the control terminal that connects with the frames 14 and 15. As a result, the light-emitting diode 1 can be lighted up in highly changeable ways.

In addition, the first light-emitting chip 20 through sixth light-emitting chip 25, which are fixed on the coupling part 11, are red chip, blue chip, green chip in sequence so as to allow the left group of light-emitting chips 20-22 and the right group of light-emitting chips 23-25 to jointly emit the required white light.

In accordance with the foregoing description, the structure of the present invention has the following advantages:

1. By using the coupling base on which a coupling part and at least two frame pairs are disposed, the light-emitting chips, which are fixed on the coupling part, are electrically connected to two frame pairs so that a single light-emitting diode can be controlled by two control terminals simultaneously.

2. By using two independent frame pairs, the light-emitting diode can be electrically connected to two different control terminals so as to provide the light-emitting diode with more changeful lighting ways.

In summary, the light-emitting diode disclosed in the present invention indeed achieves the anticipated objects. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light-emitting diode comprising:
a coupling base; a plurality of light-emitting chips; and an adhesive for sealing said coupling base, said coupling base having a coupling part and at least two frame pairs disposed therein, said light-emitting chips being fixed on said coupling part, said light-emitting chips being electrically connected with said at least two frame pairs, which are controlled by two control terminals simultaneously.

2. The light-emitting diode of claim 1, wherein said coupling part of said coupling base is a cross-shaped plate.

3. The light-emitting diode of claim 1, wherein said coupling part is located between said at least two frame pairs, and said at least two frame pairs are located around said coupling part.

4. The light-emitting diode of claim 1, wherein said coupling base has a trench formed therein.
